(19) United States
(12) Patent Application Publication
(10) Pub. No.: US 2026/0351516 A1
(43) Pub. Date: Nov. 5, 2026

(54) METHOD FOR USING MICROSCOPE DEVICE

(71) Applicant: HAMAMATSU PHOTONICS K.K., Hamamatsu-shi, Shizuoka (JP)

(72) Inventors: Akira TAKEDA, Shizuoka (JP); Daisuke OISHI, Shizuoka (JP)

(73) Assignee: HAMAMATSU PHOTONICS K.K., Hamamatsu-shi, Shizuoka (JP)

(21) Appl. No.: 19/485,873

(22) PCT Filed: May 20, 2024
(86) PCT No.: PCT/JP2024/018541

§ 371 Date: Nov. 19, 2025

(30) Foreign Application Priority Data
May 22, 2023 (JP) 2023-084004

(51) Int. Cl. H01J 37/305; H01J 37/28; H01J 37/30

(52) U.S. Cl. CPC H01J 37/3053; H01J 37/28; H01J 37/3005; H01J 2237/1526; H01J 2237/2007

(57) ABSTRACT

A method for using a microscope device includes a first step of disposing a sample inside a chamber; a second step of depressurizing the chamber by evacuating an inside of the chamber; a third step of removing a part of the sample inside the chamber by irradiating the sample with laser light through a transmissive member, which transmits the laser light, to perform ablation processing after the first step and the second step; a fourth step of performing ablation processing on particles generated from the sample by irradiating the particles with the laser light in a state where the sample is disposed inside the chamber, after the first step and the second step; and a fifth step of observing the sample using a microscope unit after the third step.

### TECHNICAL FIELD

The present disclosure relates to a method for using a microscope device.

### BACKGROUND ART

Patent Literature 1 describes a laser processing method. In this method, a workpiece is held inside a vacuum container. The vacuum container is provided with a window that transmits a laser beam. Furthermore, a laser beam emitted from a laser light source transmits through the window, and is incident on the workpiece. Accordingly, an etching phenomenon called ablation occurs on a surface of the workpiece, and the surface of the workpiece is scraped away.

### CITATION LIST

### Patent Literature

Patent Literature 1: Japanese Unexamined Patent Publication No. 2002-248589

### SUMMARY OF INVENTION

### Technical Problem

There is a demand for performing ablation processing on a sample by irradiating the sample with laser light through a transmissive member such as the window of the vacuum container as in the laser processing method described in Patent Citation 1. When ablation processing is performed on the sample, particles may be generated from the sample, and may adhere to the transmissive member. When ablation processing is continued in a situation where the particles adhere to the transparent member, the transmittance of the laser light through the transmissive member decreases, and therefore, processing quality may be decreases or unintended absorption of the laser light in the transparent member may occurs, thereby causing damage to the transmissive member.

An object of the present disclosure is to provide a method for using a microscope device that can suppress a decrease in the transmittance of a transmissive member.

### Solution to Problem

A method for using a microscope device according to the present disclosure is [1] “a method for using a microscope device, including: a first step of disposing a sample inside a chamber; a second step of depressurizing the chamber by evacuating an inside of the chamber; a third step of removing a part of the sample inside the chamber by irradiating the sample with laser light through a transmissive member, which transmits the laser light, to perform ablation processing after the first step and the second step; a fourth step of performing ablation processing on particles generated from the sample by irradiating the particles with the laser light in a state where the sample is disposed inside the chamber, after the first step and the second step; and a fifth step of observing the sample using a microscope unit after the third step. In the third step, a focal point of the laser light is located at a first position on the sample side with respect to the transmissive member in an optical axis direction of the laser light, and in the fourth step, the focal point is located at a second position on the transmissive member side with respect to the sample in the optical axis direction”.

In the method for using a microscope device, after the sample is disposed inside the chamber and the chamber is depressurized, ablation processing is performed on the sample by irradiation with the laser light through the transmissive member. Therefore, the particles generated during the ablation processing may adhere to the transmissive member (or may have already adhered to the transmissive member). In contrast, in this method, ablation processing is performed on the particles generated from the sample by irradiation with the laser light. Accordingly, the adhesion of the particles to the transmissive member can be suppressed, or adhered matter on the transmissive member can be removed. Accordingly, a decrease in the transmittance of the transmissive member can be suppressed. Incidentally, in this method, ablation processing is performed when the sample and particles generated from the sample are processed. Therefore, compared to a case in which thermal processing is performed using the laser light when the sample is processed, damage to the sample during processing is suppressed, and damage is less likely to occur in the sample even when the sample is irradiated with the laser light during processing of the particles generated from the sample. Therefore, according to this method, a decrease in the transmittance of the transmissive member can be suppressed while suppressing damage to the sample.

A method for using a microscope device according to the present disclosure may be [2] “the method for using a microscope device according to [1] above, in which the fourth step is executed after the third step”. In this case, the particles generated from the sample in the preceding third step and the adhered matter adhered to the transmissive member can be removed in the subsequent fourth step.

A method for using a microscope device according to the present disclosure may be [3] “the method for using a microscope device according to [2] above, in which the third step is executed again after the fourth step”. In this case, for example, the adhered matter removed from the transmissive member in the fourth step and adhered to the sample can be removed by executing the third step again.

A method for using a microscope device according to the present disclosure may be [4] “the method for using a microscope device according to any one of 1 to 3 above, in which, between the third step and the fourth step, a position of the focal point is changed between the first position and the second position by moving the chamber”. In this case, the position of the focal point of the laser light can be changed between the first position in the third step and the second position in the fourth step by moving the chamber.

A method for using a microscope device according to the present disclosure may be [5] “the method for using a microscope device according to any one of [1] to [4] above, in which, between the third step and the fourth step, a position of the focal point is changed between the first position and the second position by moving a lens for focusing the laser light toward the sample or the transmissive member”. In this case, the position of the focal point of the laser light can be changed between the first position in the third step and the second position in the fourth step by moving the lens.

A method for using a microscope device according to the present disclosure may be [6] “the method for using a microscope device according to any one of [1] to [5] above, in which, between the third step and the fourth step, a position of the focal point is changed between the first position and the second position using a galvanometer scanner”. In this case, the position of the focal point of the laser light can be changed between the first position in the third step and the second position in the fourth step by using the galvanometer scanner.

A method for using a microscope device according to the present disclosure may be [7] “the method for using a microscope device according to any one of [1] to [6] above, in which, between the third step and the fourth step, a position of the focal point is changed between the first position and the second position using a spatial light modulator”. In this case, the position of the focal point of the laser light can be changed between the first position in the third step and the second position in the fourth step by using the spatial light modulator.

A method for using a microscope device according to the present disclosure may be [8] “the method for using a microscope device according to [1] above, in which the fourth step is executed simultaneously with the third step”. In this case, the processing time can be shortened by simultaneously processing the sample and the particles generated from the sample.

A method for using a microscope device according to the present disclosure may be [9] “the method for using a microscope device according to [8] above, in which the third step and the fourth step are executed simultaneously by modulating the laser light using a spatial light modulator to form the focal point at both the first position and the second position”. In this case, simultaneous processing of the sample and the particles generated from the sample can be suitably performed.

A method for using a microscope device according to the present disclosure may be [10] “the method for using a microscope device according to any one of [1] to [9] above, in which a pulse width of the laser light is 1 ps or less”. In this case, ablation processing can be effectively performed.

A method for using a microscope device according to the present disclosure may be [11] “the method for using a microscope device according to any one of [1] to [10] above, in which the second position is a position within 2 mm from a surface on the sample side of the transmissive member”. In such a manner, by setting the position (second position) of the focal point of the laser light in the fourth step within 2 mm from the surface on the sample side of the transmissive member, laser intensity capable of removing adhered matter on the surface of the transmissive member can be ensured.

A method for using a microscope device according to the present disclosure may be [12] “the method for using a microscope device according to any one of [1] to [11] above, in which the second position is a position on a side opposite the sample with respect to a surface on the sample side of the transmissive member”. In such a manner, by setting the position (second position) of the focal point of the laser light in the fourth step farther away from the sample, damage to the sample can be suppressed.

A method for using a microscope device according to the present disclosure may be [13] “the method for using a microscope device according to [12] above, in which the second position is a position inside the transmissive member”. In such a manner, the position (second position) of the focal point of the laser light in the fourth step may be set inside the transmissive member.

A method for using a microscope device according to the present disclosure may be [14] “the method for using a microscope device according to [12] above, in which the second position is a position outside the transmissive member”. In such a manner, by setting the position (second position) of the focal point of the laser light in the fourth step outside the transmissive member on the side opposite the sample, a wider irradiation region of the laser light on the surface on the sample side of the transmissive member can be ensured.

A method for using a microscope device according to the present disclosure may be [15] “the method for using a microscope device according to any one of [1] to [14] above, in which, in the fourth step, the sample is irradiated with the laser light that has transmitted through the transmissive member”. As described above, in this method, since the same laser light as the laser light for ablation processing of the sample is used to process the particles generated from the sample, damage is less likely to occur in the sample even when the sample is irradiated with a portion of the laser light with which the transmissive member is irradiated in the fourth step. Therefore, in the fourth step, it is not necessary to move the sample or block the laser light such that the sample is not irradiated with a portion of the laser light.

A method for using a microscope device according to the present disclosure may be [16] “the method for using a microscope device according to any one of [1] to [15] above, in which the transmissive member is an incident portion for the laser light in the chamber”. In such a manner, the transmissive member from which adhered matter is to be removed may be the incident portion for the laser light in the chamber.

A method for using a microscope device according to the present disclosure may be [17] “the method for using a microscope device according to any one of [1] to [15] above, in which the transmissive member is a cover provided to cover the sample inside the chamber”. In such a manner, the transmissive member from which adhered matter is to be removed may be the cover provided to cover the sample.

A method for using a microscope device according to the present disclosure may be [18] “the method for using a microscope device according to any one of [1] to [17] above, in which the fourth step and the fifth step are executed in different chambers”. In such a manner, the observation of the sample in the fifth step may be performed in a chamber different from the chamber in which ablation processing is performed on the particles generated from the sample in the fourth step.

A method for using a microscope device according to the present disclosure may be [19] “the method for using a microscope device according to any one of [1] to [17] above, in which the fourth step and the fifth step are executed in the same chambers”. In such a manner, the observation of the sample in the fifth step may be performed in the same chamber as the chamber in which ablation processing is performed on the particles generated from the sample in the fourth step.

A method for using a microscope device according to the present disclosure may be [20] “the method for using a microscope device according to any one of [1] to [19] above, in which a beam pattern of the laser light is a top hat shape”. In this case, for example, in the fourth step, the particles generated from the sample can be processed more uniformly.

A method for using a microscope device according to the present disclosure may be [21] “the method for using a microscope device according to any one of [1] to [20] above, including: a first step of disposing a sample inside a chamber; a second step of depressurizing the chamber by evacuating an inside of the chamber; a third step of removing a part of the sample inside the chamber by irradiating the sample with laser light through a transmissive member, which transmits the laser light, to perform ablation processing after the first step and the second step; a fourth step of removing adhered matter on the transmissive member by irradiating the transmissive member with the laser light to perform ablation processing on the adhered matter in a state where the sample is disposed inside the chamber, after the first step and the second step; and a fifth step of observing the sample using a microscope after the third step. In the third step, a focal point of the laser light is located at a first position on the sample side with respect to the transmissive member in an optical axis direction of the laser light, and in the fourth step, the focal point is located at a second position on the transmissive member side with respect to the sample in the optical axis direction”.

In the method for using a microscope device, after the sample is disposed inside the chamber and the chamber is depressurized, ablation processing is performed on the sample by irradiation with the laser light through the transmissive member. Therefore, the particles generated during the ablation processing may adhere to the transmissive member (or may have already adhered to the transmissive member). In contrast, in this method, the adhered matter on the transmissive member is removed by irradiating the transmissive member with the laser light to perform ablation processing on the adhered matter. Accordingly, a decrease in the transmittance of the transmissive member can be suppressed. Incidentally, in this method, ablation processing is performed when the sample is processed and the adhered matter is removed. Therefore, compared to a case in which thermal processing is performed using the laser light when the sample is processed, damage to the sample during processing is suppressed, and damage is less likely to occur in the sample even when the sample is irradiated with the laser light during removal of the adhered matter. Therefore, according to this method, the adhered matter on the transmissive member can be removed while suppressing damage to the sample.

### Advantageous Effects of Invention

According to the present disclosure, it is possible to provide the method for using a microscope device that can suppress a decrease in the transmittance of the transmissive member.

### BRIEF DESCRIPTION OF DRAWINGS

FIG. 1 is a schematic view showing a part of a microscope device according to the present embodiment.

FIG. 2 is a schematic view showing the remaining portion of the microscope device shown in FIG. 1.

FIG. 3 is a flowchart showing one example of a method for using a microscope device according to the present embodiment.

FIG. 4 is a schematic view showing a step of the method for using the microscope device shown in FIG. 3.

FIG. 5 is a schematic view showing a step of the method for using the microscope device shown in FIG. 3.

FIG. 6 is a schematic view showing a step of the method for using the microscope device shown in FIG. 3.

FIG. 7 is a schematic view for describing an example of dual-focus simultaneous processing.

FIG. 8 is a schematic view showing a microscope device according to a modification example.

FIG. 9 is a flowchart showing each step when a transmissive member is cleaned in accordance with the transmittance of the transmissive member.

FIG. 10 is a schematic view showing a microscope device according to another modification example.

### DESCRIPTION OF EMBODIMENTS

Hereinafter, a method for using a microscope device according to one embodiment will be described with reference to the drawings. Incidentally, in the description of the drawings, the same or corresponding elements are denoted by the same reference signs, and duplicate descriptions may be omitted.

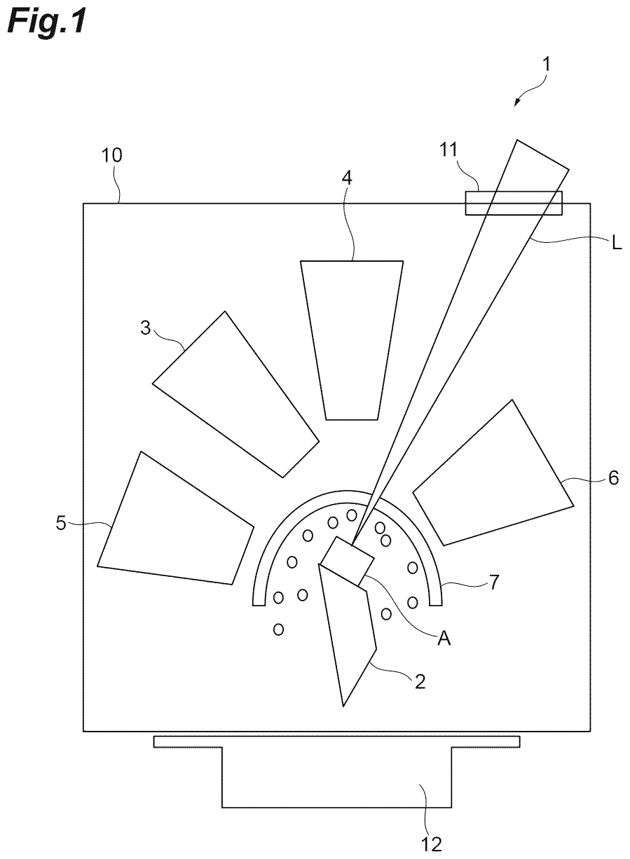

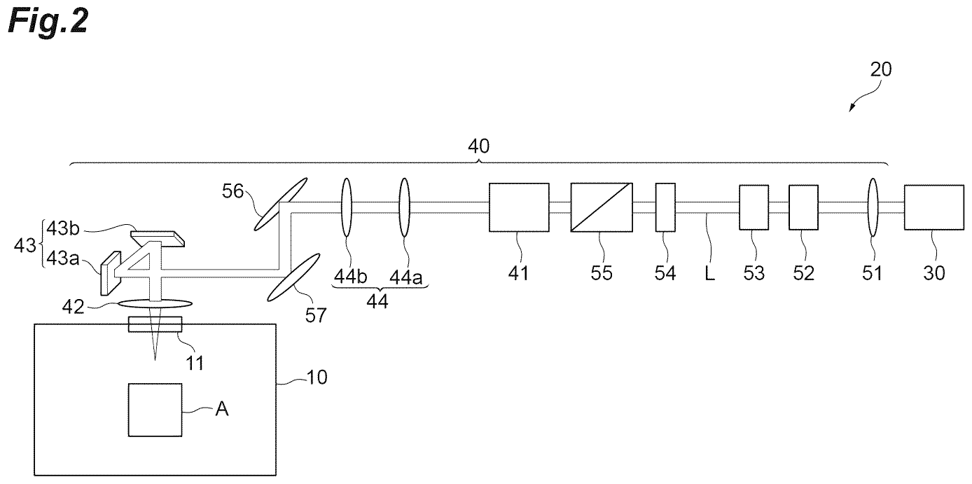

FIG. 1 is a schematic view showing a part of a microscope device according to the present embodiment. FIG. 2 is a schematic view showing the remaining portion of the microscope device shown in FIG. 1. A microscope device 1 shown in FIGS. 1 and 2 is, as will be described later, a device that includes a focused ion beam (FIB) device that performs etching on a sample by irradiating the sample with focused ions (for example, Ga ions); a scanning electron microscope (SEM) device that observes the sample by irradiating the sample with an electron beam; and a laser device that performs laser processing (here, ablation processing) on the sample by irradiating the sample with laser light, and that enables, by means of the SEM device, observation of a processed cross section of the sample formed by processing performed by the FIB device and/or the laser device.

The microscope device 1 includes a sample holder 2, a beam irradiation unit 3, a first microscope unit (microscope unit) 4, a second microscope unit (microscope unit) 5, a cover 7 (transmissive member), a chamber 10, and a laser device 20. Sample A is disposed on the sample holder 2. The sample holder 2 may support the sample A without fixing the sample A as in a case in which the sample A is simply placed, or may fix and hold the sample A, for example, through affixing or the like. Here, the sample holder 2 holds the sample A. The beam irradiation unit 3 serves to irradiate the sample A held (disposed) (hereinafter, the same) by the sample holder 2 with a focused ion beam. Therefore, the beam irradiation unit 3 may include at least a focused ion beam emission unit of the FIB device.

The first microscope unit 4 serves to observe the sample A held by the sample holder 2. More specifically, the first microscope unit 4 is configured to be able to acquire an image of the sample A (observe the sample A) by irradiating the sample A held by the sample holder 2 with an electron beam, and detecting secondary electrons or the like generated in the sample A. Therefore, the first microscope unit 4 may be at least a part of the SEM device that includes an electron beam emission unit and a detection unit.

Similarly to the first microscope unit 4, the second microscope unit 5 serves to observe the sample A held by the sample holder 2. More specifically, the second microscope unit 5 can acquire information on the crystal structure or the like of the sample A (observe the sample A) by irradiating the sample A held by the sample holder 2 with an electron beam, and detecting the electron beam scattered by the sample A. That is, as one example, the second microscope unit 5 is a part of the SEM device using an electron backscatter diffraction (EBSD) method, and may be a part of the SEM device including at least an electron beam emission unit and a detection unit. Incidentally, the microscope device 1 may include a transmission electron microscope (TEM) device instead of (or in addition to) the SEM device. In this case, the first microscope unit 4 and the second microscope unit 5 may be at least a part of the TEM device.

The cover 7 is made of a material that transmits laser light L to be described later, and is provided to cover the sample A held by the sample holder 2. Accordingly, the cover 7 may be disposed at a reference position interposed between the sample holder 2 and the beam irradiation unit 3, the first microscope unit 4, and the second microscope unit 5 in the optical path of the laser light L. Incidentally, the cover 7 is configured to be movable from the reference position such that the cover 7 is not interposed between the sample holder 2 and the beam irradiation unit 3, the first microscope unit 4, and the second microscope unit 5.

Incidentally, the cover 7 may be formed in a box shape, or may be formed in a plate shape. When the cover 7 has a box shape, the cover 7 may be formed, for example, in a rectangular box shape with one side open or in a box shape with one side open and a semicircular cross section (illustrated example). In this case, in a state where the sample A is disposed inside the box, the cover 7 may be disposed such that an open portion of the box faces the bottom portion side of the chamber 10 and a bottom portion of the box faces the side on which the beam irradiation unit 3, the first microscope unit 4, and the second microscope unit 5 are located. At this time, an edge portion of the box forming the open portion may be in contact with a bottom portion of the chamber 10, or may be spaced apart from the bottom portion of the chamber 10.

The chamber 10 accommodates the sample holder 2, the beam irradiation unit 3, the first microscope unit 4, the second microscope unit 5, and the cover 7. An incident portion 11 for the laser light L that is formed in a window shape from a material that transmits the laser light L is formed in the chamber 10. In addition, an evacuation portion 12 for depressurization (creating a vacuum) by evacuation of the inside of the chamber 10 is formed in the chamber 10. Furthermore, another unit 6 for processing or observing the sample A held by the sample holder 2 may be provided inside the chamber 10.

The laser device 20 includes a laser output unit 30 and a laser optical system 40. The laser output unit 30 serves to output the laser light L having ultrashort pulses at low fluence. The pulse width of the laser light L output from the laser output unit 30 is, for example, 1 ps or less. In addition, as one example, the fact that the laser light L has low fluence may indicate that the energy density of the laser light L is an energy density in the vicinity of a processing threshold value of the sample A, which is determined such that ablation processing is induced during laser processing of the sample A. The laser optical system 40 serves to irradiate the sample A held by the sample holder 2 with the laser light L output from the laser output unit 30. The laser light L output from the laser output unit 30 is guided by the laser optical system 40, and is incident into the chamber 10 through the incident portion 11.

The laser optical system 40 includes a spatial light modulator 41 and a galvanometer scanner 43. The spatial light modulator 41 modulates the laser light output from the laser output unit 30 in accordance with a modulation pattern, and emits the modulated laser light. More specifically, the spatial light modulator 41 is, for example, a liquid crystal on silicon-spatial light modulator (LCOS-SLM), and displays a modulation pattern on a liquid crystal layer, thereby modulating the laser light L, which is incident on and emitted from the liquid crystal layer, in accordance with the modulation pattern.

The spatial light modulator 41 can, for example, as will be described later, suppress the expansion of a spot system at the focal position of the laser light L by modulating the laser light L such that the laser light L has a plurality of focal points P in an optical axis direction B, or modulating the laser light L to correct aberrations occurring when the laser light passes through the transmissive member such as the cover 7 or the incident portion 11.

The galvanometer scanner 43 includes mirrors 43a and 43b, and irradiates the sample A held by the sample holder 2 with the laser light L emitted from the spatial light modulator 41, while scanning the sample A by driving the mirrors 43a and 43b. The laser light L emitted from the galvanometer scanner 43 is focused toward the sample A by a lens 42. The lens 42 is, for example, an fθ lens.

The laser optical system 40 includes a relay optical system 44. The relay optical system 44 is disposed between the spatial light modulator 41 and the galvanometer scanner 43. The relay optical system 44 includes a pair of lenses 44a and 44b, and serves to transfer an image of the laser light L modulated by the spatial light modulator 41 onto the lens 42. The optical path of the laser light L emitted from the spatial light modulator 41 and passing through the relay optical system 44 is adjusted by predetermined mirrors 56 and 57, and the laser light L is then provided to the galvanometer scanner 43.

The laser optical system 40 further includes a collimating lens 51, an output control unit (adjustment unit) 52, a beam diameter control unit (adjustment unit) 53, a half-wave plate 54, and a polarizing beam splitter 55 that are disposed in order on the optical path of the laser light L from the laser output unit 30 toward the spatial light modulator 41. The collimating lens 51 collimates the laser light L output from the laser output unit 30, and emits the collimated laser light L. Therefore, the collimated laser light L is incident on the spatial light modulator 41. The collimating lens 51 may be omitted.

The output control unit 52 is, for example, an attenuator, and adjusts the output of the laser light L output from the laser output unit 30. The beam diameter control unit 53 is, for example, a beam expander, and adjusts the beam diameter of the laser light L output from the laser output unit 30. In such a manner, the output control unit 52 and the beam diameter control unit 53 are disposed between the spatial light modulator 41 and the laser output unit 30, and function as the adjustment units that adjust the output and beam diameter of the laser light L.

The half-wave plate 54 changes the polarization direction of the laser light L output from the laser output unit 30. The polarizing beam splitter 55 splits the laser light L, which is output from the laser output unit 30 and is incident through the half-wave plate 54, into an s-polarized component and a p-polarized component. The p-polarized component (p-polarized laser light L) is incident on the spatial light modulator 41. As described above, the laser light L incident on the spatial light modulator 41 is modulated and then incident into the chamber 10 through the galvanometer scanner 43, and is provided for scanning of the sample A.

In the microscope device 1 described above, the processing of the sample A using a focused ion beam from the beam irradiation unit 3 and the processing of the sample A using the laser light L from the laser device 20 can be performed. When a focused ion beam is used, the sample A can be processed and observed with high accuracy. On the other hand, when the laser light L is used, a large area of the sample A can be processed and observed with high throughput.

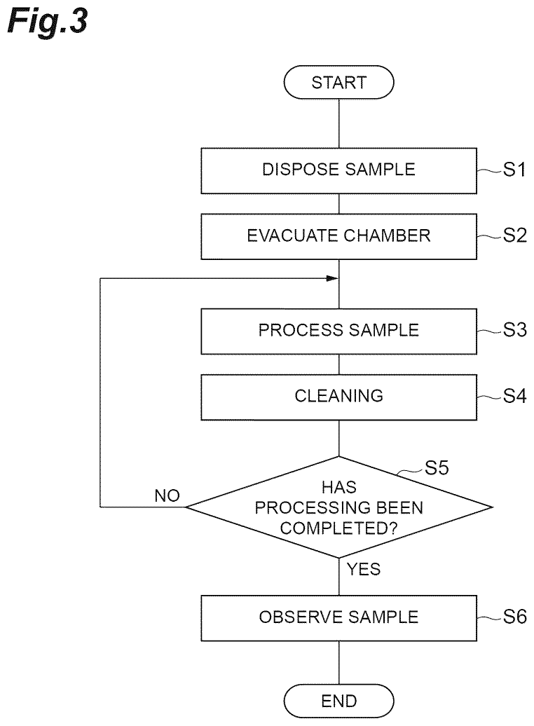

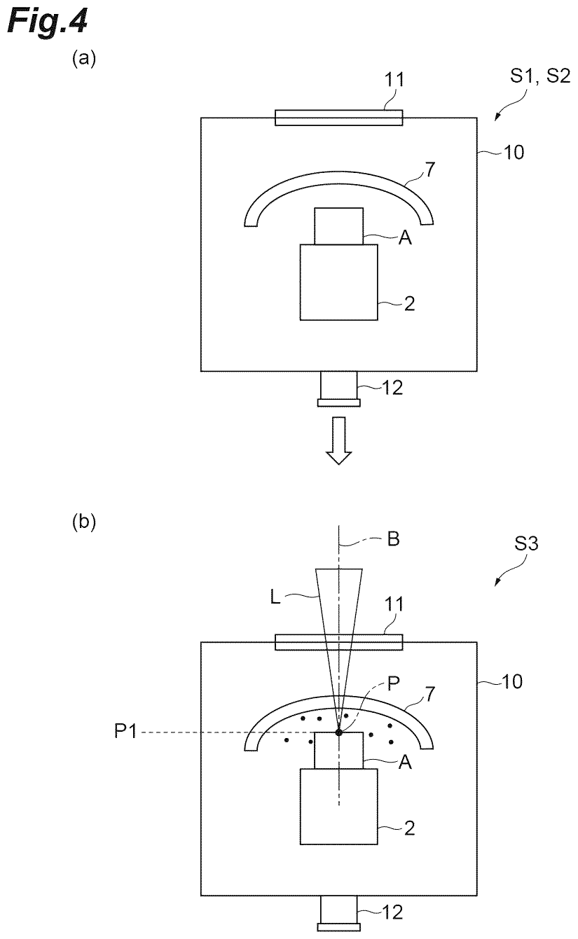

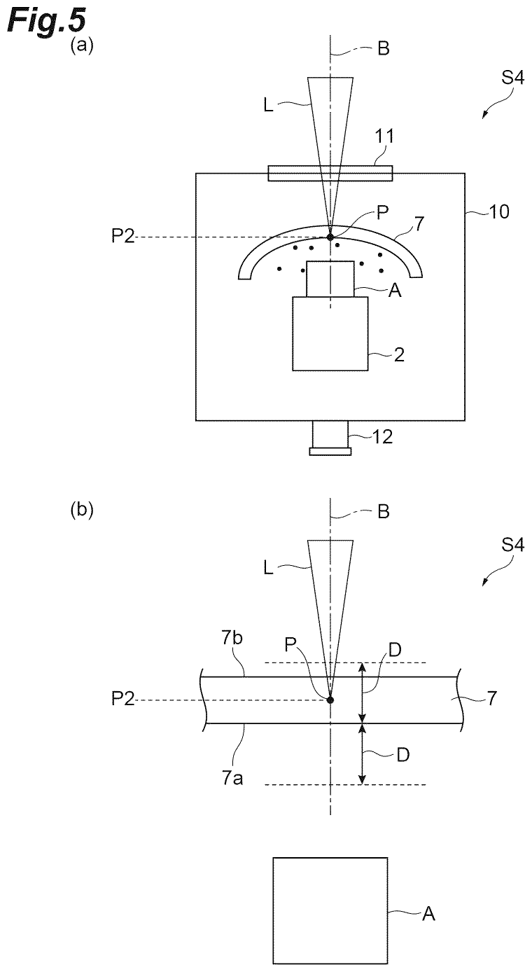

Subsequently, a method for using the microscope device described above will be described. FIG. 3 is a flowchart showing one example of the method for using a microscope device according to the present embodiment. FIGS. 4 and 5 are schematic views showing steps of the method for using a microscope device shown in FIG. 3. Incidentally, FIGS. 4 and 5, the beam irradiation unit 3, the first microscope unit 4, the second microscope unit 5, and the unit 6 of the microscope device 1 shown in FIG. 1 are not illustrated.

As shown in FIG. 3 and (a) of FIG. 4, in the method for using the microscope device 1 according to the present embodiment, first, the sample A is disposed inside the chamber 10 (step S1, first step). In step S1, the sample A is held by the sample holder 2. Next, the chamber 10 is depressurized (a vacuum is created) by evacuating the inside of the chamber 10 using the evacuation portion 12 (step S2, second step).

Next, as shown in FIG. 3 and (b) of FIG. 4, a part of the sample A inside the chamber 10 is removed by irradiating the sample A with the laser light L through the incident portion 11 and the cover 7, which transmit the laser light L, to perform ablation processing (step S3, third step). At this time, particles are generated from the sample A. In step S3, the sample A is scanned (irradiated) with the laser light L while the focal point P of the laser light L is located at a first position P1 on the sample A side with respect to the cover 7 in the optical axis direction B of the laser light L. The first position P1 is, as one example, the position where the laser light L is focused on a surface on the cover 7 side of the sample A.

Incidentally, as one example, in the method for using the microscope device 1 according to the present embodiment, the number of times ablation processing is performed on the sample A in step S3 may be set in advance, and step S3 may be executed for only the number of times. In addition, thermal processing is processing in which a portion of a sample is removed by melting the sample through an increase in the temperature of the sample caused by the absorption of laser light by the sample. In contrast, ablation processing is a type of non-thermal processing in which a part of the sample A in an irradiation region of the laser light L is instantaneously decomposed and scattered by cutting the bonds between the molecules or atoms of the sample A using the energy of the laser light L.

Next, as shown in FIG. 3 and (a) of FIG. 5, in a state where the sample A is disposed inside the chamber 10, adhered matter on the cover 7 are removed (the cover 7 is cleaned) by irradiating the cover 7 with the laser light L to perform ablation processing on the adhered matter (step S4, fourth step). In step S4, in addition to (or instead of) the ablation processing of the adhered matter on the cover 7, by irradiating the particles (particles that may become adhered matter on the cover 7), which are generated from the sample A during the ablation processing of the sample A in step S3, with laser light L, ablation processing is performed on the particles. That is, in step S4, ablation processing is performed on the particles generated from the sample A by irradiating the sample A with the laser light L. In step S4, the same laser light L as the laser light L for the ablation processing of the sample A in step S3 is used. In such a manner, in the method for using the microscope device 1 according to the present embodiment, step S4 is executed after step S3.

The cover 7 includes a surface 7a on the sample A side and a surface 7b that is a surface on the side opposite the surface 7a (incident portion 11 side), and that is an incident surface for the laser light L. As shown in (b) of FIG. 5, in step S4, the focal point P of the laser light L is located at a second position P2 on the cover 7 side with respect to the sample A in the optical axis direction B, and the surface 7a of the cover 7 is scanned (irradiated) with the laser light L. In such a manner, the distance between the first position P1 where the focal point P of the laser light L is located in step S3 and the sample A is shorter than the distance between the first position P1 and the cover 7, and the distance between the second position P2 where the focal point P of the laser light L is located in step S4 and the cover 7 is shorter than the distance between the second position P2 and the sample A. That is, the first position P1 is located on the sample A side with respect to the second position P2.

The second position P2 is a position within a predetermined distance D from the surface 7a on the sample A side of the cover 7. The distance D is, for example, 2 mm. In addition, the second position P2 may be a position closer to the sample A side than to the surface 7a of the cover 7, or may be a position on the side opposite the sample A with respect to the surface 7a of the cover 7. When the second position P2 is a position on the side opposite the sample A with respect to the surface 7a of the cover 7, the second position P2 may be a position inside the cover 7, or may be a position outside the cover 7. The irradiation region of the laser light L on the surface 7a can be expanded by shifting the second position P2 (that is, the focal point P) from the surface 7a along the optical axis direction B. Particularly, the amount of shift of the focal point P from the surface 7a along the optical axis direction B can be adjusted such that the irradiation region of the laser light L on the surface 7a is expanded while the energy density of the laser light L on the surface 7a is maintained at a level equal to or greater than a threshold value for removing adhered matter.

Incidentally, step S4 is executed in a state where the sample A is disposed inside the chamber 10. Therefore, in step S4, a portion of the laser light L with which the cover 7 is irradiated may transmit through the cover 7, and irradiates the sample A. In addition, as one example, in the method for using the microscope device 1 according to the present embodiment, the number of times ablation processing is performed on the adhered matter on the cover 7 (or ablation processing of the particles generated from the sample A) in step S4 may be set in advance, and step S4 may be executed only the number of times.

As described above, in the method for using the microscope device 1 according to the present embodiment, between step S3 and step S4, the position of the focal point P of the laser light L is changed (switched) between the first position P1 and the second position P2. Various methods can be employed to switch the position of the focal point P of the laser light L.

For example, between step S3 and step S4, by driving a stage for supporting the chamber 10 to move the chamber 10, the position of the focal point P may be changed between the first position P1 and the second position P2. In addition, between step S3 and step S4, the position of the focal point P may be changed between the first position P1 and the second position P2 by moving the lens 42 for focusing the laser light L toward the sample A or the cover 7.

Alternatively, between step S3 and step S4, the position of the focal point P may be changed between the first position P1 and the second position P2 using the galvanometer scanner 43. In addition, between step S3 and step S4, the position of the focal point P may be changed between the first position P1 and the second position P2 using the spatial light modulator 41. Furthermore, a combination of at least any two of the above-described methods can also be used.

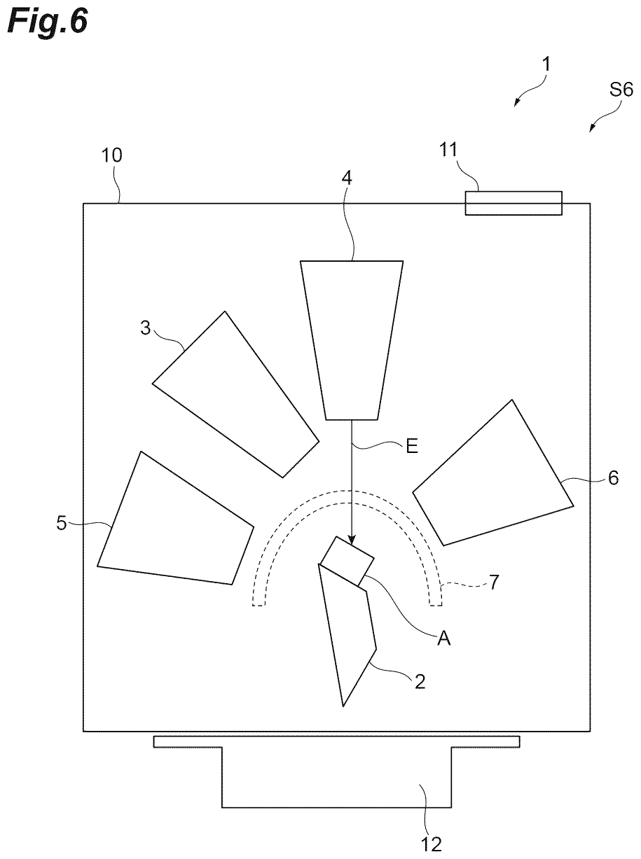

In the next step, it is determined whether the intended processing of the sample A has been completed (step S5). As one example, in step S5, by setting in advance the number of times laser processing is performed (for example, the number of times step S3 is executed), and determining whether the laser processing has been completed the set number of times, it can be determined whether the intended processing of the sample A has been completed. When it is determined in step S5 that the intended processing of the sample A has not been completed (step S5: NO), step S3 to step S5 are executed again. On the other hand, when it is determined in step S5 that the intended processing of the sample A has been completed (step S5: YES), as shown in FIG. 6, the sample A is observed using the first microscope unit 4 or the second microscope unit 5 disposed inside the chamber 10 (step S6, fifth step).

In step S6, first, the cover 7 is moved from the reference position such that the cover 7 is not interposed between the sample A and both the first microscope unit 4 and the second microscope unit 5. Thereafter, the sample A can be observed by irradiating the sample A with an electron beam E from the first microscope unit 4 or the second microscope unit 5 (in the illustrated example, the first microscope unit 4).

As described above, in the method for using the microscope device 1 according to the present embodiment, after the sample A is disposed inside the chamber 10 and the chamber 10 is depressurized, ablation processing is performed on the sample A by irradiation with the laser light L through the cover 7. Therefore, the particles generated during the ablation processing may adhere to the cover 7 (or may have already adhered to the cover 7).

In contrast, in the method for using the microscope device 1 according to the present embodiment, ablation processing is performed on the particles generated from the sample A by irradiation with the laser light L. Accordingly, the adhesion of the particles to the cover 7 can be suppressed, or adhered matter on the cover 7 can be removed. Accordingly, a decrease in the transmittance of the cover 7 can be suppressed. As a result, according to this method, since the reduced frequency of replacement of the cover 7 enables continuous processing, large-volume removal processing can be performed on one sample A, or a plurality of the samples A can be processed without breaking the vacuum inside the chamber 10. Incidentally, in this method, ablation processing is performed when the sample and particles generated from the sample are processed. Therefore, compared to a case in which thermal processing is performed using the laser light L when the sample A is processed, damage to the sample A during processing is suppressed, and damage is less likely to occur in the sample A even when the sample A is irradiated with the laser light L during processing of the particles generated from the sample A. Therefore, according to this method, a decrease in the transmittance of the cover 7 can be suppressed while suppressing damage to the sample A.

In addition, in the method for using the microscope device 1 according to the present embodiment, adhered matter on the cover 7 is removed by irradiating the cover 7 with the laser light L to perform ablation processing on the adhered matter. Accordingly, a decrease in the transmittance of the cover 7 can be suppressed. Therefore, according to this method, the adhered matter on the cover 7 can be removed while suppressing damage to the sample A.

Incidentally, the wavelength of the laser light L during ablation processing of the sample A may be a wavelength absorbed by the sample A, or may be a wavelength not absorbed by the sample A. If the wavelength of the laser light L is a wavelength absorbed by the sample A, damage to the sample A is suppressed compared to thermal processing. Furthermore, when the wavelength of the laser light L is a wavelength not absorbed by the sample A, damage to the sample A is further suppressed.

In addition, in the method for using the microscope device 1 according to the present embodiment, step S4 is executed after step S3. Therefore, the adhered matter generated in the preceding step S3 and adhered to the cover 7 (or the particles generated from the sample A) can be removed in the subsequent step S4.

In addition, in the method for using the microscope device 1 according to the present embodiment, between step S3 and step S4, the position of the focal point P may be changed between the first position P1 and the second position P2 by moving the chamber 10. In this case, the position of the focal point P of the laser light L can be changed between the first position P1 in step S3 and the second position P2 in step S4 by moving the chamber 10.

In addition, in the method for using the microscope device 1 according to the present embodiment, between step S3 and step S4, the position of the focal point P may be changed between the first position P1 and the second position P2 by moving the lens 42 for focusing the laser light L toward the sample A or the cover 7. In this case, the position of the focal point P of the laser light L can be changed between the first position P1 in step S3 and the second position P2 in step S4 by moving the lens 42.

In addition, in the method for using the microscope device 1 according to the present embodiment, between step S3 and step S4, the position of the focal point P may be changed between the first position P1 and the second position P2 using the galvanometer scanner 43. In this case, the position of the focal point P of the laser light L can be changed between the first position P1 in step S3 and the second position P2 in step S4 by using the galvanometer scanner 43.

In addition, in the method for using the microscope device 1 according to the present embodiment, between step S3 and step S4, the position of the focal point P may be changed between the first position P1 and the second position P2 using the spatial light modulator 41. In this case, the position of the focal point P of the laser light L can be changed between the first position P1 in step S3 and the second position P2 in step S4 by using the spatial light modulator 41.

In addition, in the method for using the microscope device 1 according to the present embodiment, the pulse width of the laser light L is 1 ps or less. Therefore, ablation processing can be effectively performed.

In addition, in the method for using the microscope device 1 according to the present embodiment, the second position P2 may be a position within 2 mm from the surface 7 a on the sample A side of the cover 7. In such a manner, by setting the position (second position P2) of the focal point P of the laser light L in step S4 within 2 mm from the surface 7a on the sample A side of the cover 7, laser intensity capable of removing adhered matter on the surface 7a of the cover 7 can be ensured.

In addition, in the method for using the microscope device 1 according to the present embodiment, the second position P2 may be a position on the side opposite the sample A with respect to the surface 7a on the sample A side of the cover 7. In such a manner, by setting the position (second position P2) of the focal point P of the laser light L in step S4 farther away from the sample A, damage to the sample A can be suppressed.

In addition, in the method for using the microscope device 1 according to the present embodiment, the second position P2 may be a position inside the cover 7. In such a manner, the position (second position P2) of the focal point P of the laser light L in step S4 may be set inside the cover 7.

In addition, in the method for using the microscope device 1 according to the present embodiment, the second position P2 may be a position outside the cover 7. In such a manner, by setting the position (second position P2) of the focal point P of the laser light L in step S4 outside the cover 7 on the side opposite the sample A, a wider irradiation region of the laser light L on the surface 7a on the sample A side of the cover 7 can be ensured.

In addition, in the method for using the microscope device 1 according to the present embodiment, in step S4, the sample A may be irradiated with the laser light L that has transmitted through the cover 7. As described above, in this method, since the same laser light L as the laser light L for ablation processing of the sample A is used to process the particles generated from the sample A, damage is less likely to occur in the sample A even when the sample A is irradiated with a portion of the laser light L with which the cover 7 is irradiated in step S4. Therefore, in step S4, it is not necessary to move the sample A or block the laser light L such that the sample A is not irradiated with a portion of the laser light L.

Furthermore, in the method for using the microscope device 1 according to the present embodiment, step S4 and step S6 are executed in the same chamber 10. In such a manner, the observation of the sample A in step S5 may be performed in the same chamber 10 as the chamber in which ablation processing is performed on the particles generated from the sample A in step S4. In this case, movement of the sample A between step S4 and step S6 becomes unnecessary, so that high-accuracy processing and observation can be performed.

The above embodiment has described one aspect of the method for using a microscope device according to the present invention. Therefore, the method for using a microscope device according to the present invention is not limited to the method for using the microscope device 1 described above, and may be arbitrarily changed. Subsequently, modification examples will be described.

In the above-described embodiment, an example in which step S4 is executed after step S3 is performed has been described; however, the order of step S3 and step S4 is not limited thereto. For example, when the microscope device 1 has already been used, adhered matter may be already adhered to the cover 7. Therefore, step S4 may be executed prior to the execution of step S3.

In addition, after step S3 and step S4 are executed in order, step S3 may be executed again. In this case, the adhered matter removed from the cover 7 in step S4 and adhered to the sample A can be removed by executing step S3 again.

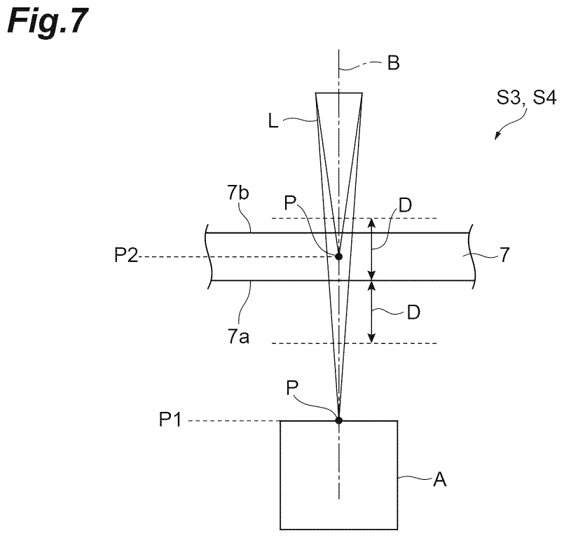

Furthermore, step S3 and step S4 may be executed simultaneously. In this case, the focal point P of the laser light L is formed at both the first position P1 and the second position P2. To achieve this, as one example, as shown in FIG. 7, the laser light L can be modulated by the spatial light modulator 41 such that the focal point P of the laser light L is formed at each of the first position P1 and the second position P2 at overlapping positions along the optical axis direction B (dual-focus simultaneous processing). That is, step S3 and step S4 can be executed simultaneously by modulating the laser light L using the spatial light modulator 41 to form the focal point P at both the first position P1 and the second position P2. Incidentally, when dual-focus simultaneous processing is performed, the laser light L may be modulated by the spatial light modulator 41 such that the respective focal points P of the laser light L are formed at the first position P1 and the second position P2 not to overlap each other along the optical axis direction B (that is, to be shifted from each other in a plane direction intersecting the optical axis direction B).

As another example, step S3 and step S4 may be executed simultaneously by using an optical element having a function of branching light to branch the laser light L into two branched beams, and focusing each of the two branched beams to form the focal point P at each of the first position P1 and the second position P2. In this case as well, the respective focal points P at the first position P1 and the second position P2 may overlap each other along the optical axis direction B, or may not overlap each other.

As still another example, step S3 and step S4 may be executed simultaneously by outputting two laser lights L from the laser output unit 30 and focusing each of the two laser lights L to form the focal point P at each of the first position P1 and the second position P2. In this case as well, the respective focal points P at the first position P1 and the second position P2 may overlap each other along the optical axis direction B, or may not overlap each other. As described above, if step S3 and step S4 are executed simultaneously, the sample A and the particles generated from the sample A are processed simultaneously, and therefore, the processing time can be shortened.

In addition, in the above-described embodiment, the cover 7 has been provided as an example of a transmissive member for the laser light L from which adhered matter is to be removed. However, when the microscope device 1 does not include the cover 7, or when the microscope device 1 includes the cover 7 but adhered matter may also adhere to the incident portion 11 of the chamber 10, the transmissive member to be cleaned may be the incident portion 11 (and the cover 7).

In addition, in the above-described embodiment, a case in which all processing and observation including step S3, step S4, and step S6 are performed inside the same chamber 10 has been provided as an example. However, step S6 and both step S3 and step S4 may be executed in different chambers. In such a manner, the observation of the sample A in step S6 may be performed in a chamber different from the chamber 10 in which ablation processing in step S3 and step S4 is performed. In this case, the adhesion of the particles generated during the ablation processing to the first microscope unit 4 and the second microscope unit 5 is suppressed, and a decrease in the accuracy of observation of the sample A is suppressed.

In addition, the beam pattern of the laser light L may have a top hat shape. In this case, for example, in step S4, the particles generated from the sample A can be processed more uniformly. In addition, in this case, processing over a wide range can be performed compared to the case of using the laser light L having a Gaussian distribution.

Furthermore, in the above-described embodiment, an example in which after ablation processing is performed on the sample A in step S3 only the number of times set in advance, the cleaning of the transmissive member (in the above-described embodiment, the cover 7) (ablation processing of the particles generated from the sample A) is performed in step S4 has been provided. According to this method, adhered matter that accumulates on the transmissive member as step S3 is executed a plurality of times can be efficiently removed, and the transmittance of the transmissive member can be effectively maintained. On the other hand, after step S3 is executed, the transmittance of the transmissive member can be measured, and step S4 can also be executed in accordance with the measurement result to clean the transmissive member.

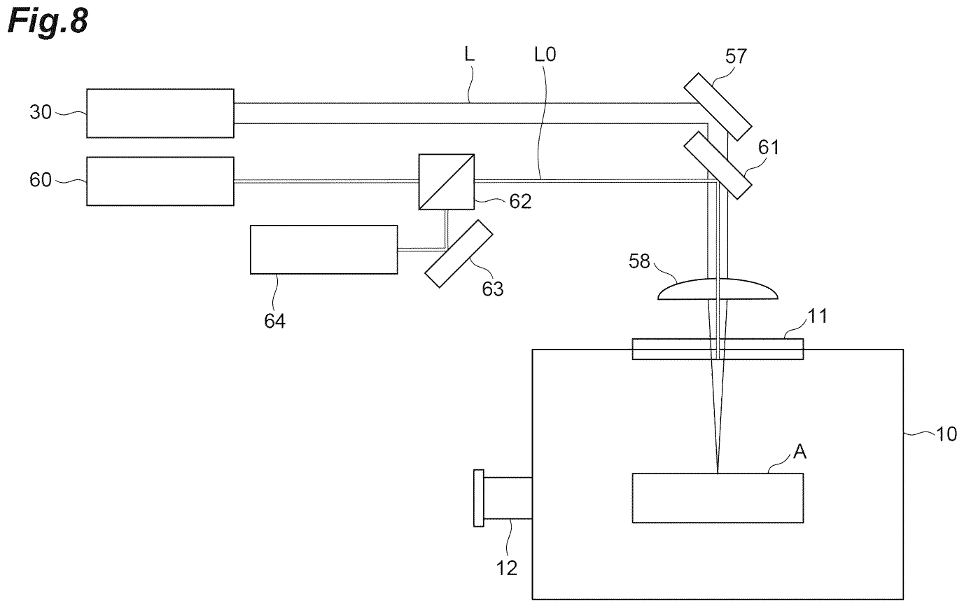

In this case, as shown in FIG. 8, the microscope device 1 can include a configuration for measuring the transmittance of the transmissive member. Incidentally, in FIG. 8, the beam irradiation unit 3, the first microscope unit 4, the second microscope unit 5, and the unit 6 are not illustrated. In addition, in FIG. 8, the incident portion 11 of the chamber 10 is provided as an example of a transmissive member to be cleaned.

In the example of FIG. 8, the microscope device 1 includes a laser output unit 60, a dichroic mirror 61, a beam splitter 62, a mirror 63, and a detector 64. In addition, for example, the laser light L output from the laser output unit 30 passes through the laser optical system 40 (not illustrated), is reflected by the mirror 57, is incident on the lens 58 through the dichroic mirror 61, and is focused toward the sample A or the incident portion 11.

The laser output unit 60 outputs laser light L0 for measurement having a wavelength different from that of the laser light L for processing output from the laser output unit 30. The laser light L0 output from the laser output unit 60 is incident on the dichroic mirror 61 through the beam splitter 62, is reflected, and is focused toward the incident portion 11 by the lens 58. A portion of the laser light L0 incident on the incident portion 11 is reflected by a surface 11a on the sample A side of the incident portion 11. The reflected light of the laser light L0 is guided through the lens 58, the dichroic mirror 61, the beam splitter 62, and the mirror 63, and is incident on and detected by the detector 64. Accordingly, the transmittance of the incident portion 11 is measured.

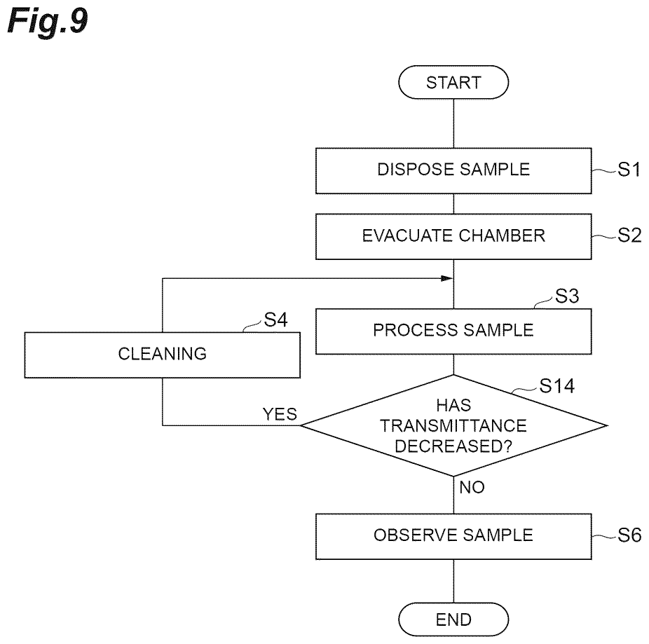

FIG. 9 is a flowchart showing each step when the transmissive member (incident portion 11) is cleaned in accordance with the transmittance of the transmissive member. As shown in FIG. 9, here, similarly to the above-described embodiment, step S1, step S2, and step S3 are executed. Thereafter, the transmittance of the incident portion 11 is measured using the configuration shown in FIG. 8, and it is determined whether the measured transmittance has decreased by a predetermined threshold value or more (step S14).

When it is determined in step S14 that the transmittance of the incident portion 11 has not decreased by the predetermined threshold value or more (step S14: NO), step S6 (the observation of the sample A) is executed similarly to the above-described embodiment. On the other hand, when it is determined in step S14 that the transmittance of the incident portion 11 has decreased by the predetermined threshold value or more (step S14: YES), the incident portion 11 is cleaned similarly to the above-described embodiment (step S4). That is, by irradiating the incident portion 11 with the laser light L, ablation processing is performed on adhered matter on the surface on the sample A side of the incident portion 11, and the adhered matter is removed.

Incidentally, after the determination in step S14 and before step S6 is executed, similarly to step S5, it can be determined whether the intended processing of the sample A has been completed. In this case, by setting in advance the number of times laser processing is performed (for example, the number of times step S3 is executed), and determining whether the laser processing has been completed the set number of times, it can be determined whether the intended processing of the sample A has been completed. Then, when it is determined that the intended processing of the sample A has been completed, the observation of the sample A in step S6 as described above can be executed.

As described above, by cleaning the incident portion 11 based on the transmittance of the incident portion 11, the incident portion 11 can be efficiently cleaned a necessary and sufficient number of times.

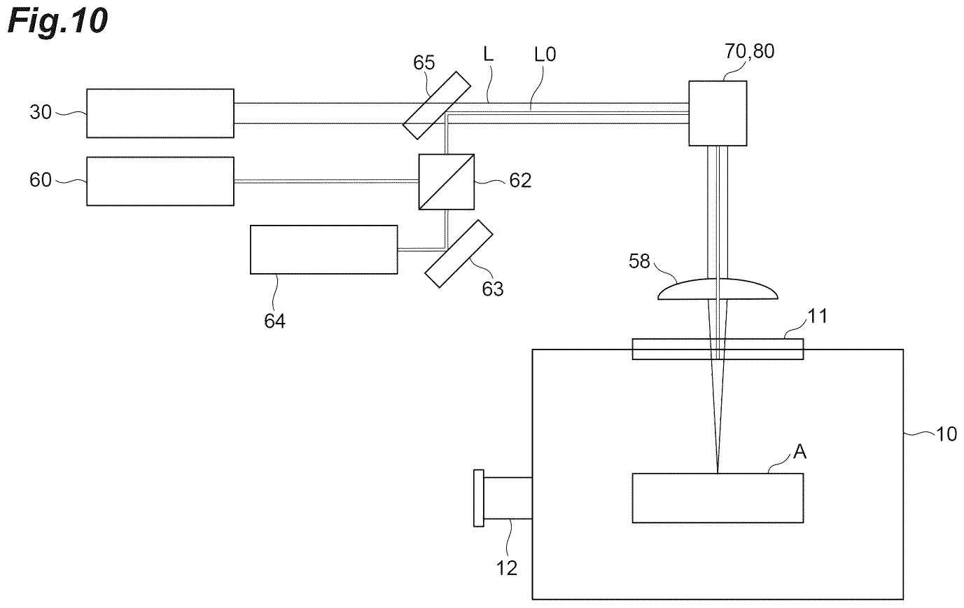

Incidentally, the configuration for measuring the transmittance of the incident portion 11 is not limited to the example of FIG. 8, and may be, for example, the configuration shown in FIG. 10. In the example of FIG. 10, the microscope device 1 includes the laser output unit 60, the beam splitter 62, the mirror 63, the detector 64, a dichroic mirror 65, and a galvanometer scanner 70. The dichroic mirror 65 and the galvanometer scanner 70 are disposed in order on the optical path of the laser light L. Accordingly, for example, the laser light L output from the laser output unit 30 passes through the laser optical system 40 (not illustrated) and the dichroic mirror 65, is reflected by the galvanometer scanner 70, is incident on the lens 58, and is focused toward the sample A or the incident portion 11.

The laser light L0 output from the laser output unit 60 is incident on the dichroic mirror 65 through the beam splitter 62, is reflected by the dichroic mirror 65 and the galvanometer scanner 70 in order, and is focused toward the incident portion 11 by the lens 58. A portion of the laser light L0 incident on the incident portion 11 is reflected by the surface 11a on the sample A side of the incident portion 11. The reflected light of the laser light L0 is guided through the lens 58, the galvanometer scanner 70, the dichroic mirror 65, the beam splitter 62, and the mirror 63, and is incident on and detected by the detector 64. Accordingly, the transmittance of the incident portion 11 is measured. Incidentally, in the configuration shown in FIG. 10, a reflective spatial light modulator 80 may be provided instead of the galvanometer scanner 70.

Incidentally, in the microscope device 1, the beam irradiation unit 3 is not essential and may be omitted. In addition, the microscope device 1 may include a cooling portion for cooling the spatial light modulator 41. In this case, thermal influence on the spatial light modulator 41 is suppressed.

In addition, in the microscope device 1, the laser optical system 40 includes the collimating lens 51 for causing the collimated laser light L to be incident on the spatial light modulator 41. However, when collimated light is output from the laser output unit 30, the collimating lens 51 may be omitted.

In addition, in the microscope device 1, one of the first microscope unit 4 and the second microscope unit 5 may be omitted, and it is sufficient that at least one microscope unit is provided. Furthermore, in the microscope device 1, one or both of the output control unit 52 and the beam diameter control unit 53 and the relay optical system 44 can also be omitted.

Furthermore, in the above-described embodiment, in step S6, a case in which the sample A is observed using the first microscope unit 4 or the second microscope unit 5 disposed inside the chamber 10 has been provided as an example. However, in step S6, the present invention is not limited to observation using the first microscope unit 4 or the second microscope unit 5 disposed inside the chamber 10, and the sample A may be observed using a microscope unit disposed outside the chamber 10. In this case, at least one of the first microscope unit 4 and the second microscope unit 5 may be disposed outside the chamber 10 (for example, inside a chamber separate from the chamber 10), and may be used for observation in step S6.

### REFERENCE SIGNS LIST

1: microscope device, 4: first microscope unit (microscope unit), 5: second microscope unit (microscope unit), 7: cover (transmissive member), 10: chamber, 11: incident portion (transmissive member), 41: spatial light modulator, 42: lens, 43: galvanometer scanner.

1. A method for using a microscope device, comprising:
a first step of disposing a sample inside a chamber;
a second step of depressurizing the chamber by evacuating an inside of the chamber;
a third step of removing a part of the sample inside the chamber by irradiating the sample with laser light through a transmissive member, which transmits the laser light, to perform ablation processing after the first step and the second step;
a fourth step of performing ablation processing on particles generated from the sample by irradiating the particles with the laser light in a state where the sample is disposed inside the chamber, after the first step and the second step; and
a fifth step of observing the sample using a microscope unit after the third step,
wherein, in the third step, a focal point of the laser light is located at a first position on the sample side with respect to the transmissive member in an optical axis direction of the laser light, and
in the fourth step, the focal point is located at a second position on the transmissive member side with respect to the sample in the optical axis direction.

2. The method for using a microscope device according to claim 1,
wherein the fourth step is executed after the third step.

3. The method for using a microscope device according to claim 2,
wherein the third step is executed again after the fourth step.

4. The method for using a microscope device according to claim 1,
wherein, between the third step and the fourth step, a position of the focal point is changed between the first position and the second position by moving the chamber.

5. The method for using a microscope device according to claim 1,
wherein, between the third step and the fourth step, a position of the focal point is changed between the first position and the second position by moving a lens for focusing the laser light toward the sample or the transmissive member.

6. The method for using a microscope device according to claim 1,
wherein, between the third step and the fourth step, a position of the focal point is changed between the first position and the second position using a galvanometer scanner.

7. The method for using a microscope device according to claim 1,
wherein, between the third step and the fourth step, a position of the focal point is changed between the first position and the second position using a spatial light modulator.

8. The method for using a microscope device according to claim 1,
wherein the fourth step is executed simultaneously with the third step.

9. The method for using a microscope device according to claim 8,
wherein the third step and the fourth step are executed simultaneously by modulating the laser light using a spatial light modulator to form the focal point at both the first position and the second position.

10. The method for using a microscope device according to claim 1,
wherein a pulse width of the laser light is 1 ps or less.

11. The method for using a microscope device according to claim 1,
wherein the second position is a position within 2 mm from a surface on the sample side of the transmissive member.

12. The method for using a microscope device according to claim 1,
wherein the second position is a position on a side opposite the sample with respect to a surface on the sample side of the transmissive member.

13. The method for using a microscope device according to claim 12,
wherein the second position is a position inside the transmissive member.

14. The method for using a microscope device according to claim 12,
wherein the second position is a position outside the transmissive member.

15. The method for using a microscope device according to claim 1,
wherein, in the fourth step, the sample is irradiated with the laser light that has transmitted through the transmissive member.

16. The method for using a microscope device according to claim 1,
wherein the transmissive member is an incident portion for the laser light in the chamber.

17. The method for using a microscope device according to claim 1,
wherein the transmissive member is a cover provided to cover the sample inside the chamber.

18. The method for using a microscope device according to claim 1,
wherein the fourth step and the fifth step are executed in different chambers.

19. The method for using a microscope device according to claim 1,
wherein the fourth step and the fifth step are executed in the same chambers.

20. (canceled)

21. The method for using a microscope device according to claim 1,
wherein, in the fourth step, adhered matter on the transmissive member is removed by irradiating the transmissive member with the laser light to perform ablation processing on the adhered matter.
